(19) United States
(12) Patent Application Publication
(10) Pub. No.: US 2010/0264023 A1
(43) Pub. Date: Oct. 21, 2010

(54) METHOD FOR PRODUCING METAL NITRIDE FILM, METAL OXIDE FILM, METAL CARBIDE FILM OR FILM OF COMPOSITE MATERIAL THEREOF, AND PRODUCTION APPARATUS THEREFOR

(75) Inventors: Mayumi TAKEYAMA, Kitami-shi (JP); Atsushi NOYA, Kitami-shi (JP)

Correspondence Address: THE NATH LAW GROUP, 112 South West Street, Alexandria, VA, 22314, US

(73) Assignee: NATIONAL UNIVERSITY CORPORATION KITAMI INSTUTUTE OF TECHNOLOGY, Kitami-shi (JP)

(21) Appl. No.: 12/767,403

(22) Filed: Apr. 26, 2010

Related U.S. Application Data
(62) Division of application No. 12/308,702, filed on Dec. 22, 2008.

(30) Foreign Application Priority Data
Jun. 22, 2006 (JP) 2006-172584

(51) Int. Cl. C23C 14/34

(52) U.S. Cl. 204/298.13; 204/298.15

(57) ABSTRACT

Disclosed is a production apparatus for producing on a substrate a film selected from the group consisting of a metal nitride film, a metal oxide film, a metal carbide film and a film of composite material thereof. The production apparatus comprises a substrate holder for supporting the substrate; a chamber capable retaining a reduced pressure therein; an inert gas supply section that supplies inert gas into the chamber; a source gas supply section that supplies a source gas containing atoms selected from the group consisting of nitrogen atoms, oxygen atoms and carbon atoms into the chamber; a target containing a constituent element of a metal film to be formed on the substrate; a pair of sputtering electrodes for sputtering the target using the inert gas supplied from the gas supply section as a sputtering gas; and a metal catalyst which generates radicals by activating the source gas and which is placed outside a plasma region formed by the pair of sputtering electrodes.

### CROSS-REFERENCE TO RELATED APPLICATION

This application is a division of application Ser. No. 12/308,702, filed Dec. 22, 2008, which was the National Stage of International Application No. PCT/JP2007/062620, filed Jun. 22, 2007.

### FIELD OF THE INVENTION

The present invention relates to a method for producing a metal nitride film, a metal oxide film, a metal carbide film or a film of composite material thereof, and a production apparatus therefor. The present invention further relates to a coating film formed of the metal nitride film, metal oxide film, metal carbide film or film of composite material thereof, and a manufacturing method for a semiconductor device including the metal nitride film, metal oxide film, metal carbide film or film of composite material thereof.

### BACKGROUND OF THE INVENTION

Currently, metal films reacted with specific atoms (e.g., nitride metal films, oxide metal films or carbide oxide films) have been attracting attention in the automobile field and in the optics field, as well as in the semiconductor field. These metal films can have any desired characteristics (e.g., film thickness, resistance, or insulating property) by appropriately selecting the kinds of constituent metals and additional atoms, or their combinations, finding applications as barriers, antireflection films, transparent electrodes, insulating films, surface-hardened films etc.

The characteristics required for metal nitride films, metal oxide films and metal carbide films differ depending on the intended purpose. For example, SiO₂ films which have been used as interlayer dielectric films for silicon ULSI chips are required to be replaced by materials having small permittivity in order to reduce parasitic capacitance. The reason for this is that in silicon ULSI chips with copper interconnections, signal delay due to increased RC time constant is increasingly remarkable to an extent that influences overall circuit performance, and this RC time constant is defined by the interconnection resistance of all interconnections, including barriers, and by the parasitic capacitance between interconnections. Thus, currently, there is a demand for new interlayer dielectric films with low permittivity that can replace SiO₂ films and can achieve reduction in the resistance of interconnections and barriers as well as in the parasitic capacitance between interconnections.

Reducing the barrier thickness and reducing the barrier material resistance are both known as effective methods of reducing interconnection resistance. Heretofore, in order to realize low interconnection resistance, there have been many extensive studies that aim to reduce the barrier thickness as much as possible, with TaNₓ materials being exclusively targeted as the barrier material. However, the current expectation is that, by merely attempting to reduce barrier thickness, there would be no film deposition methods available that can produce ultra-thin barrier films in the next 45-nm technology node and beyond. For this reason, various studies directed to reduction in the barrier material resistance have emerged, which was not studied much before.

In recent years, as barrier films replacing TaNₓ films, films made of metal nitrides of the Group IV metals (HfN, ZrN, and TiN) have been focused. This is because nitrides of these metals are the most thermally stable of all transition metal nitrides (i.e., the value for the standard heats of formation is negative and large), have low resistance, and show good adhesion. Among these metal nitride films, TiN films are widely used by virtue of relatively easy access to raw materials.

Cu interconnections are increasingly used in place of Al interconnections as low-resistance interconnections. Accordingly, in addition to thinness, barriers are required to meet the following requirements: (1) capability of preventing Cu diffusion during heat treatment at around 400-500° C.; (2) non-reactivity to Cu and interlayer dielectric films during heat treatment at around 400-500 ° C.; (3) good adhesion to Cu and interlayer dielectric films; (4) minimum possible solid solubility with Cu; (5) minimum possible low resistance (upper limit=300 μΩcm) ; and (6) thermal stability.

However, recent studies revealed that the thermal stability of barriers formed of the above metal nitrides decreases when combined with Cu interconnections. One possible cause of this is that barrier materials such as TiN tend to have columnar structure, i.e., column-shaped crystal grains, resulting in the formation of shorter, linear Cu diffusion paths that undesirably enhance Cu diffusion that causes thermal stability reduction.

So far, the present inventors revealed the relationship between the structure and characteristics of barrier materials, and established that even the same barrier material shows different characteristics according to its structure and texture (see Non-Patent Documents 1 and 2). In these studies, the present inventors prepared a generally available polycrystalline barrier, a highly oriented barrier and a nanocrystalline barrier, and evaluated their barrier characteristics. As a result, it was established that, in view of achieving ultra-thin barriers, nanocrystalline or amorphous structure is suitable as the barrier structure. In these studies, the highly oriented barrier was prepared as a barrier comparable to epitaxially grown barriers, and the nanocrystalline barrier was prepared in stead of an amorphous barrier because amorphous barriers generally have very high resistance.

As the method for forming a metal nitride film as a barrier, chemical film deposition methods and physical film deposition methods are generally available. Examples of the film deposition method using chemical reactions include chemical vapor deposition (CVD). This method supplies a vaporized raw material containing constituent metal atoms of a metal nitride film, metal oxide film or metal carbide film to be produced (source gas) and a gas containing nitrogen, oxygen or carbon atoms (carrier gas) to a surface of a substrate placed in a chamber, allowing chemical reactions (e.g., decomposition, reduction, and substitution) to take place over the substrate surface by application of energy such as heat, plasma or light for depositing a thin film on the substrate. However, films prepared by CVD generally have high resistance and, during manufacture, are likely to incorporate impurities since the metal elements in the source gas exist in the state of a compound rather than an element. In addition, it is difficult with this method to produce ultra-thin films of the order of a few nanometers. Although films with moderate quality can be obtained at deposition temperatures around 350-400° C., the film quality is very poor compared to that attained by reactive sputtering to be described later.

Atomic layer deposition (ALD) is proposed as a method for producing a ultra-thin film by using CVD as a basic technology (see Non-Patent Document 3). This method first prepares a monolayer of metal atoms by appropriately adjusting the surface adsorption conditions, or a metal film which is as thin as the monolayer by appropriately adjusting the source gas flow rate, and then applies a raw material gas containing nitrogen atoms to the monolayer or metal film to effect surface reactions. This process is then repeated to deposit a metal nitride film or the like, which has a desired thickness. It may however be necessary in this method to carry out one or more cycles of this process in order to form layers of metal monolayers as a continuous layer. In addition, ALD requires new equipment exclusive to ALD film deposition and thus causes cost increase. Moreover, the ALD method basically uses the same source gas material as the CVD method and thus may, in some cases, produce films with somewhat lower resistance than that of films produced by CVD. Nevertheless, the obtainable film resistance is, at most, near the upper limit (300 μmΩcm) below which the resultant film is operable as a barrier, and the film contains a large amount of unwanted impurities. Furthermore, in view of the nature of ALD that film deposition occurs by utilizing surface adsorption reactions, film deposition itself becomes difficult depending on the kind of substrate material. For this reason, in this method, attention needs to be paid to the type of substrate material.

In particular, when a metal nitride film is deposited onto interconnections, it is necessary to set the deposition temperature around 400° C. or below so as to reduce thermal influences on the interconnections. For example, although a TiN film with high thermal stability can be obtained by thermal CVD using TiCl₄+NH₃ as a source gas, it is necessary to set the deposition temperature to 500° C. or higher. In general, as organic metal sources (raw material) capable of low-temperature film deposition, tetrakisdiethylaminotitanium (TDEAT), tetrakisdimethylaminotitanium (TDMAT), etc., are known. In order for these compounds to be fully thermally decomposed, temperatures of 350° C. or higher are required; therefore, deposition temperature cannot be reduced drastically. Moreover, since they contain carbon atoms, the resultant film has high concentrations of hydrocarbon groups and thus carbon atoms and hydrogen atoms are ejected by heat treatment during manufacture. For this reason, it becomes likely that unstable films, which have problems of high resistance and poor barrier characteristics, are produced.

Regarding physical film deposition methods for metal nitride films, reactive sputtering is currently focused. Reactive sputtering includes the steps of bombarding a metal plate called “target” with a mixture gas of ionized inert gas (e.g., ionized argon gas) and nitrogen-containing reactive gas; allowing metal atoms ejected by the bombardment to react with nitrogen, oxygen or carbon atoms on a substrate or target or in a plasma to form metal nitride, metal oxide or metal carbide; and depositing it onto the substrate to form a thin film thereon. The metal nitride film or the like produced by reactive sputtering may be generally of high quality compared to those produced by CVD. However, reactive sputtering requires relatively high temperatures in order to chemically combine the ejected metal atoms with nitrogen atoms or the like.

To overcome these disadvantages there are various studies that aim to develop a production method that can produce metal nitride films with low resistance and high reliability at low deposition temperatures. For example, one proposed method produces a metal nitride film by forming a metal film on a substrate by PE-CVD and by subjecting it to plasma treatment while keeping the substrate temperature at 300° C. (see Patent Document 1).
Patent Document 1: Japanese Patent Application Laid-Open No.2004-363402
Non-Patent Document 1: M. B. Takeyama, T. Itoi, E. Aoyagi, A. Noya, Applied Surface Science 190, pp. 450-454 (2002)
Non-Patent Document 2: M. B. Takeyama, A. Noya, K. Sakanishi, j. Vac. Sci Technol. b18, pp. 1333-1337 (2000)
Non-Patent Document 3: G. Beyer, A. Satta, j. Schuhmacher, K. Maex, W. Besling, O. Kilpela, H. Sprey, G. Tempel, Microelectronic Engineering, Vol. 64, pp. 233-245 (2002)

### SUMMARY OF THE INVENTION

In recent years, as substrates for semiconductor devices, plastic substrates are often used in addition to semiconductor substrates made of Si, SiGe, compound semiconductors, etc. While plastic substrates are advantageous in terms of flexibility and weight, they are susceptible to heat than metal substrates. Accordingly, it is required in the art to lower the deposition temperature when forming a metal nitride film, metal oxide film, metal carbide film or film of composite material thereof onto a plastic substrate. In this regard, it is desired that the temperature of a film being deposited be lower than the temperature at which the plastic substrate is made, i.e. the formation temperature of the plastic substrate, although it is desirably around room temperature. Many of general-purpose plastic substrate materials deteriorate at 200-300° C. However, as in Patent Documents 1 and 2 above, reactive sputtering requires a film deposition temperature of around 300-400° C. for producing films with low resistance. When the film deposition temperature is 300° C. or below, the resistance of the resultant barrier drastically increases as the film deposition temperature decreases; when it is around room temperature, the resistance increases to as high as several hundreds of ohm-centimeters. Moreover, since some heat energy is required to excite nitrogen atoms and the like in the reactive gas, it is unrealistic to lower the film deposition temperature to 300° C. or below.

When attempting to form a ultra-thin metal film using a sputtering method (e.g., reactive sputtering), it is often the case that high aspect-ratio pits cannot be filled up with the film. Thus, there is a concern that sputtering methods would not be applicable as the film deposition methods that can accommodate the 65-nm technology node and beyond. As a general trend in the industry, a three-layered barrier composed of a Ta barrier (3 nm), a TaN barrier (1 nm) and a Ta barrier (3 nm) is used, wherein the Ta barriers are deposited by sputtering and the TaN barrier is deposited by ALD. Therefore, a continuous film with a thickness around 3 nm may be formed even by sputtering. There are some reports about successful formation of a metal film like the above three-layered barrier by means of sputtering, but no reports have been made that indicate successful formation of a single ultra-thin (thickness=3-5 nm) layer of metal nitride by sputtering.

Accordingly, a first object of the present invention is to provide a method that enables production of a metal nitride film, a metal oxide film, a metal carbide film or a film of composite material thereof, which are ultra-thin films with low resistance, at low temperatures, particularly a method of producing a ultra-thin metal nitride film having low resistance and thickness of the order of nanometers. A second object of the present invention is to provide a method of manufacturing a semiconductor device that includes a coating layer and/or barrier which are formed of a metal nitride film produced by the above method.

The present invention relates to the following methods of producing a film selected from the group consisting of a metal nitride film, a metal oxide film, a metal carbide film and a film of composite material thereof.
[1] A method for producing on a substrate a film selected from the group consisting of a metal nitride film, a metal oxide film, a metal carbide film and a film of composite material thereof, including:

a first step of forming a metal film on the substrate by physical vapor deposition; and

a second step of allowing radicals, which have been generated by bringing a source gas containing atoms selected from the group consisting of nitrogen atoms, oxygen atoms and carbon atoms into contact with a metal catalyst, to react with the metal film.
[2] The method according to [1], wherein sputtering is used as the physical vapor deposition.
[3] The method according to [1] or [2], wherein the metal film to be reacted with the radicals is not heated at all or retained at 300° C. or below.
[4] The method according to any one of [1] to [3], wherein a cycle of the first and second steps is performed once or repeated.
[5] The method according to any one of [1] to [4], wherein the source gas contains a nitrogen atom.
[6] The method according to any one of [1] to [5], wherein the source gas is ammonia or nitrogen gas.
[7] The method according to anyone of [1] to [6],wherein the metal film is a film made of a metal selected from the Groups III to VI in the periodic table.
[8] The method according to anyone of [1] to [7], wherein the metal film is a film made of titanium, zirconium, hafnium, niobium, tantalum, molybdenum, tungsten, vanadium or chrome, or a film made of an alloy of any combination thereof.
[9] The method according to any one of [1] to [8], wherein the metal catalyst is a metal selected from the group consisting of tungsten, molybdenum, tantalum, titanium, vanadium, platinum, and nickel-chrome alloy.
[10] The method according to anyone of [1] to [9], wherein the film selected from the group consisting of a metal nitride film, a metal oxide film, a metal carbide film and a film of composite material thereof is a coating film.
[11] The method according to any one of [1] to [10], wherein the film selected from the group consisting of a metal nitride film, a metal oxide film, a metal carbide film and a film composite material thereof is a barrier for a semiconductor device.

The present invention further relates to the following manufacturing methods for a semiconductor device.
[12] A method for manufacturing a semiconductor device that includes a substrate, an interlayer dielectric film formed on the substrate, a barrier formed on the interlayer dielectric film, and a metal interconnection formed on the barrier, including:

a first step of preparing a metal film on an interlayer dielectric film by physical vapor deposition; and

a second step of forming a barrier selected from the group consisting of a metal nitride film, a metal oxide film, a metal carbide film and a film of composite material thereof by allowing radicals, which have been generated by bringing a source gas containing atoms selected from the group consisting of nitrogen atoms, oxygen atoms and carbon atoms into contact with a metal catalyst, to react with the metal film.
[13] The method according to [12], wherein the metal film to be reacted with the radicals is not heated at all or retained at 300° C. or below.
[14] The method according to [12] or [13], wherein a cycle of the first and second steps is performed once or repeated.
[15] The method according to any one of [12] to [14], wherein the interlayer dielectric film is a film made of SiO₂ or low-permittivity material.
[16] The method according to any one of [12] to [15], wherein the metal interconnection is a copper interconnection, aluminum interconnection or tungsten interconnection.

The preset invention further relates to the following production apparatus for producing a film selected from the group consisting of a metal nitride film, a metal oxide film, a metal carbide film and a film of composite material thereof.
[17] A production apparatus for producing on a substrate a film selected from the group consisting of a metal nitride film, a metal oxide film, a metal carbide film and a film composite material thereof, including:

a substrate holder for supporting the substrate;

a chamber capable retaining a reduced pressure therein;

an inert gas supply section that supplies inert gas into the chamber;

a source gas supply section that supplies a source gas containing atoms selected from the group consisting of nitrogen atoms, oxygen atoms and carbon atoms into the chamber;

a target containing a constituent element of a metal film to be formed on the substrate;

a pair of sputtering electrodes for sputtering the target using the inert gas supplied from the gas supply section as a sputtering gas; and

a metal catalyst which generates radicals by activating the source gas and which is placed outside a plasma region formed by the pair of sputtering electrodes.
[18] The production apparatus according to [17], wherein the pair of sputtering electrodes and metal catalyst are placed in the same chamber.
[19] The production apparatus according to [17], wherein the pair of sputtering electrodes is placed in a different chamber than the metal catalyst.
[20] A production apparatus for producing on a substrate a film selected from the group consisting of a metal nitride film, a metal oxide film, a metal carbide film and a film of composite material thereof, including:

a substrate holder for supporting the substrate;

a chamber capable retaining a reduced pressure therein;

a source gas supply section that supplies a source gas containing atoms selected from the group consisting of nitrogen atoms, oxygen atoms and carbon atoms into the chamber;

a metal evaporation source containing a constituent element of a metal film to be formed;

a heating mechanism for heating the metal evaporation source; and

a metal catalyst which generates radicals by activating the source gas and which serves as, or is placed near the heating mechanism.

The present invention relates to the following films selected from the group consisting of a metal nitride film, a metal oxide film, a metal carbide film or a film composite, material thereof
[21] A metal nitride film, metal oxide film, metal carbide film or film of composite material thereof which has an amorphous structure or nanocrystalline structure which does not undergo structural change by heat treatment at 500° C.
[22] A metal nitride film having an amorphous structure which has a resistance of 300 μΩcm or less.
[23] A metal nitride film, metal oxide film, metal carbide film or film of composite material thereof in which the concentration of nitrogen atoms, oxygen atoms or carbon atoms can be changed per several to several tens of nanometers along the thickness.
[24] A metal carbide film having a nanocrystalline structure.

The present invention can provide a film selected from the group consisting of a metal nitride film, a metal oxide film, a metal carbide film and a film of composite material thereof (hereinafter also referred to collectively as a “metal nitride film or the like”) at low temperatures. In addition, when a metal film is used as a metal sputtering film to be reacted with radicals, a metal nitride film or the like with high quality can be obtained. Furthermore, by selecting an appropriate metal, it is possible to produce a metal nitride film or the like with low resistance. Thus, the production method of the present invention may also be used for the production of barriers for use for a semiconductor device including thermally unstable interlayer dielectric material (low-permittivity material).

The production method of the present invention for producing a metal nitride film or the like is realized by a vapor deposition apparatus employing a conventional physical vapor deposition method, including a sputtering apparatus, in which a metal is placed as a metal catalyst for generating radicals. Thus, the production method of the present invention eliminates the need to introduce new equipment and is advantageous in terms of costs.

### BRIEF DESCRIPTION OF DRAWINGS

FIG. 1 shows an example of a production apparatus for a metal nitride film or the like according to the present invention;

FIG. 2 shows an x-ray diffraction pattern (a) of a titanium nitride film produced by the production method of the present invention, and an x-ray diffraction pattern (b) of a titanium nitride film produced by reactive sputtering;

FIG. 3 shows an X-ray diffraction pattern of a hafnium nitride film produced by the production method of the present invention;

FIG. 4 shows X-ray diffraction patterns, as measured by the θ-2θ method, of a structure containing a titanium nitride film produced by the production method of the present invention, with pattern (a) measured before heat treatment and pattern (b) measured after heat treatment;

FIG. 5 shows X-ray diffraction patterns, as measured by the θ-2θ method, of a structure containing a titanium nitride film produced by reactive sputtering, with pattern (a) measured before heat treatment and pattern (b) measured after heat treatment;

FIG. 6 shows X-ray diffraction patterns, as measured by the θ-2θ method, of a structure containing a hafnium nitride film produced by the production method of the present invention, with pattern (a) measured before heat treatment and pattern (b) measured after heat treatment;

FIG. 7 shows X-ray diffraction patterns, as measured by the thin-film method, of a structure containing a hafnium nitride film produced by the production method of the present invention, with pattern (a) measured before heat treatment and pattern (b) measured after heat treatment;

FIG. 8 shows X-ray diffraction patterns, as measured by the θ-2θ method, of a structure containing a hafnium nitride film produced by the production method of the present invention, with pattern (a) measured before heat treatment and pattern (b) measured after heat treatment;

FIG. 9 shows X-ray diffraction patterns, as measured by the thin film method, of a structure containing a hafnium nitride film produced by the production method of the present invention, with pattern (a) measured before heat treatment and pattern (b) measured after heat treatment;

FIG. 10A shows measurements of X-ray reflection by a structure containing a titanium nitride film produced by the production method of the present invention, as measured before heat treatment;

FIG. 10B shows measurements of X-ray reflection by a structure containing a titanium nitride film produced by the production method of the present invention, as measured after heat treatment;

FIG. 11A is a cross-sectional TEM image of a structure containing a titanium nitride film produced by the present invention, as taken before heat treatment; and

FIG. 11B is a cross-sectional TEM image of a structure containing a titanium nitride film produced by the present invention, as taken after heat treatment.

### DETAILED DESCRIPTION OF THE INVENTION

Hereinafter, a production method of the present invention for producing a metal nitride film or the like will be described. This method is directed to produce a film selected from the group consisting of a metal nitride film, a metal oxide film, a metal carbide film and a film of composite material thereof on a surface of a substrate, and includes the steps of (A) forming a metal film on the substrate by physical vapor deposition; and (B) allowing radicals, which have been generated by bringing a source gas containing atoms selected from the group consisting of nitrogen atoms, oxygen atoms and carbon atoms into contact with a metal catalyst, to react with the metal film.

Among the metal films produced in the present invention, the metal nitride film is only required to be a nitrided film, and additional reaction(s) such as oxidation and carbonization may have occurred therein. More specifically, the metal nitride film encompasses a metal oxynitride film, a metal carbonitride film, etc. Similarly, the metal oxide film encompasses a metal oxynitride film, a metal carboxide film, etc, and the metal carbide film encompasses a metal carboxide film, a metal carbonitride film, etc. Thus, a metal film in which two or more of nitridation, oxidation and carbonization occurred referred to as a “film of composite.”

Metals for the metal nitride film or the like to be produced are not specifically limited, but metals of the Groups III to VI in the periodic table and alloys of any combination thereof are preferable. In particular, when the metal nitride film or the like according to the present invention is used as a barrier for a semiconductor device, preferred examples of metals are titanium, zirconium, hafnium, niobium, tantalum, molybdenum, tungsten, vanadium, and chromium. In order to obtain a barrier with low resistance, the metal is preferably titanium, zirconium, hafnium, vanadium, or niobium, etc. Moreover, when the resultant film is intended for use as a coating film, preferred metals are titanium, zirconium, hafnium, vanadium, chrome, and alloys thereof (e.g., zirconium-titanium alloy).

The place where a metal film is to be provided maybe a surface of a material intended to be coated with a desired metal nitride film or the like. When the resultant metal nitride film or the like is intended for use as a barrier for a semiconductor device, it is preferably formed (1) directly on a surface of a substrate (e.g., silicon substrate); (2) on an interlayer dielectric film formed on the substrate; (3) on a capping layer; (4) or on an interconnection. Examples of the materials of the interlayer dielectric film include SiO₂ and low-permittivity materials, etc.

The metal film according to the present invention may be formed by physical vapor deposition. Thin film deposition schemes by physical vapor deposition can be broadly classified into vacuum evaporation, sputtering, and ion plating. Vacuum evaporation refers to a method including the steps of heating and vaporizing a solid material under a high level of vacuum (10⁻⁴ Pa or below) and allowing the steam to contact a substrate retained at a certain temperature to deposit a thin film thereon. Here, examples of the means of heating the solid material (metal film source) include, but not specifically limited to, resistive heating, electron beams, lasers, and high-frequency induction heating.

The sputtering method is not specifically limited and, for example, 2-pole sputtering which is a basic sputtering system utilizing plasma generated by DC glow discharge or by high-frequency waves; 3-pole sputtering in which a hot electron-discharging hot cathode is added to a 2-pole sputtering system; magnetron sputtering in which a magnetic field is applied to the target surface for stabilizing plasma; an ion beam method in which high-energy ion beams are applied to the target; or facing target sputtering in which two targets are placed in parallel and a magnetic field is vertically applied to the target surfaces can be employed.

The ion plating method is a method including the steps of ionizing atoms or molecules of a vaporized material and accelerating them so as to collide with a highly negatively charged substrate for deposition thereon. Examples of the ion plating method include, but not specifically limited to, those methods relating to ionization of vaporized thin material—basic technology of ion plating—such as a DC discharge excitation system, high-frequency discharge excitation system, hot cathode system; ion beam method; and hollow cathode discharge (HCD) method utilizing both of vaporization and ionization by electron beams. Note that physical vapor deposition methods utilizing chemical reactions, such as reactive sputtering and reactive ion plating, are not applied in the present invention.

The target from which a metal film is made may be appropriately selected according to the kind of the constituent metals of the metal films to be produced. The thickness of the metal film is not specifically limited and can be determined according to the desired thickness of a metal nitride film or the like to be produced. The thickness of the metal film may be, for example, several nanometers (e.g., 1-10 nm) or greater. When the metal film is made thin, a film with a high concentration of nitrogen, oxygen or carbon atoms can be obtained by subsequent reaction with radicals for nitridation, oxidation or carbonization.

When the metal film has a thickness of several nanometers, it can be readily reacted with radicals entirely in the subsequent step (B), thereby enabling formation of a metal nitride film or the like with a high concentration of nitrogen atoms or other atoms and, for example, a metal nitride film in which metal atoms and nitrogen atoms have been reacted in equal amounts. In order to form a metal sputtering film with a thickness of several nanometers, it is required that crystalline grains of the metal film be reduced to form nanocrystals. In some cases, a nanocrystalline metal layer may be obtained by mixing a trace amount of impurity with inert gas to be ionized. Examples of the impurity to be mixed include nitrogen, oxygen and carbon. When a metal nitride film is to be formed, nitrogen gas may be preferable; when a metal oxide film is to be formed, oxygen gas may be preferable; and when a metal carbide film is to be formed, hydocarbon gas may be preferable. The impurity amount maybe very small to an extent that causes no adverse influences on the subsequent reactions with radicals.

The production method of the present invention includes a step of allowing radicals containing nitrogen, oxygen or carbon atoms to react with the metal film. These radicals may be generated by contact of a metal catalyst with a source gas containing nitrogen, oxygen or carbon atoms. The source gas is not specifically limited as long as it can generate radicals, but is preferably a gas that generates radicals by contact with a given met al catalyst.

Examples of the source gas containing nitrogen atoms include ammonia gas, nitrogen gas, nitrogen trifluoride, hydrazine, and methylamine. Among them, ammonia gas can easily generate nitrizing radicals. Examples of the source gas containing oxygen atoms include oxygen gas. Examples of the source gas containing carbon atoms include CₓH_{y}, with CH₄ being preferable.

One or more kinds of source gases may be brought in contact with a metal catalyst. For example, when a nitrogen-containing gas and an oxygen-containing gas are combined, the metal film can be oxidized and nitrided at a time to form a metal oxynitride film. Moreover, when a gas containing both oxygen and carbon atoms, i.e., carbon dioxide gas is used, the metal film can be oxidized and carbonized at a time to form a metal carboxide film.

As described above, the gas is either partially or entirely radicalized by contact with a metal catalyst. As the metal catalyst, any high-melting point metal or noble metal can be employed; specific examples thereof include tungsten, molybdenum, tantalum, titanium, vanadium, platinum, and nickel-chrome alloy. The metal catalyst is appropriately selected according to the kind of gas to be radicalized. For example, when the temperature required for gas radicalization is relatively low (450-600° C.), NiCr or the like may be used. On the other hand, when the temperature required for radicalization is relatively high (1,500° C. or higher), Ta or W may be used. When a metal that is reactive with a metal catalyst, such as Ti or V, is used, care should be taken to avoid deterioration of the metal itself during nitridation, oxidization or carbonization. Similarly, when Ta is used, care should be taken to avoid deterioration of the metal itself during oxidization. To avoid deterioration of metal catalyst, a noble metal such as Pt is preferable.

The metal catalyst preferably has a wire shape, filament shape or mesh shape. Moreover, the metal catalyst to be brought in contact with gas is preferably heated. The heating method is not specifically limited; for example, the metal catalyst is heated by feeding a current through it. When a nitrogen-containing gas or the like contacts the metal catalyst heated in this way, the gas is thermally decomposed to generate radicals derived from nitrogen atoms or the like in the gas.

The generated radicals are then reacted with a metal film to produce a metal nitride film, a metal oxide film or a metal carbide film. The metal film to be reacted with the radicals remains non-heated or kept at 300° C. or below. Within a temperature range of not greater than 300° C., the heating temperature is not specifically limited and may be room temperature or higher. Conventionally, the metal film to be reacted with radicals is heated to higher temperatures. In the present invention, on the other hand, a high-quality metal nitride film or the like can be obtained at temperatures as low as 300° C. or below, or even at temperatures as low as 100° C. or below, or without performing heat treatment, by appropriately allowing a metal film prepared by physical vapor deposition to react with radicals generated using a metal catalyst. The metal nitride film or the like produced in this way is of low resistance and high quality compared to, for example, those produced by reactive sputtering, as also demonstrated in Examples described later.

In recent years, low-permittivity materials are replacing SiO₂—conventional materials for interlayer dielectric films—in the manufacture of integrated circuits having semiconductor devices attached on a Si substrate. Because low-permittivity materials are generally susceptible to heat, demand has arisen to reduce the process temperature, particularly the barrier deposition temperature. As described above, the present invention can produce a metal nitride film or the like at low temperatures or without heat treatment. As it is becoming necessary to arrange semiconductor devices on a plastic substrate along with recent developments of electric paper and displays, it is keenly demanded to lower the film deposition temperature as plastic substrates themselves are susceptible to heat. The present invention can be used for film deposition onto such a plastic substrate, as described above.

Because the production method of the present invention is so configured that high-energy radicals are reacted with a metal film produced by physical vapor deposition, metal films that are generally deemed less reactive can be nitrided, oxidized or carbonized. Examples of such less reactive metals include metals of the Group VI of the periodic table, including metals that hardly undergo nitridation reaction, etc., such as tungsten and molybdenum.

The period during which radicals are reacted with a metal film may be determined according to the intended concentration of nitrogen, oxygen or carbon atoms in the resultant film. This reaction generally terminates in 5-15 minutes. By shortening the reaction time or reducing the feed rate of the source gas, it is possible to reduce the concentration of nitrogen atoms in the resultant metal nitride film and to nitridize only the near-surface area of the metal film, for example. On the other hand, by increasing the reaction time, it is possible to increase the nitrogen atoms in the resultant metal nitride film and to nitridize the metal film entirely, for example. When the metal nitride film is intended for use as a coating film, it is only necessary for the film to be nitridized in the near-surface region; therefore, in this case, the reaction time may be made shorter. Where necessary, the produced metal nitride film or the like may be subjected to additional heat treatment.

In the production method of the present invention, a cycle of the above steps (A) and (B) may be performed once or repeated. By repeating this cycle, metal nitride films can be deposited on top of one another continuously and thereby the film thickness as a whole can be gradually increased. This realizes on-demand production of a metal nitride film or the like with a desired thickness, e.g., from several to several tens of nanometers.

The concentration of nitrogen, oxygen or carbon atoms in the metal film produced in each cycle can be altered by appropriately adjusting the conditions of the step (A) and/or step (B). Examples of parameters to be adjusted in each step include metal film thickness, pressure of gas to be radicalized, reaction time between metal film and radicals, and distance between metal catalyst and metal film. For example, by repeating the above cycle of the steps (A) and (B), a metal nitride film can be obtained that has different concentrations of nitrogen, oxygen or carbon atoms per several to several tens of nanometers (e.g., 1-100 nm) along the thickness. Thus, it is also possible to produce a metal film in which the concentration of nitrogen, oxygen or carbon atoms changes in the thickness direction. When titanium nitride and hafnium nitride are mononitrides in which metal atoms and nitrogen atoms are contained in almost equal amounts, they are known to show gold color. The production method of the present invention can also produce gold-color films of titanium nitride and hafnium nitride. This demonstrates that nitridization can be fully effected in the metal film in the present invention.

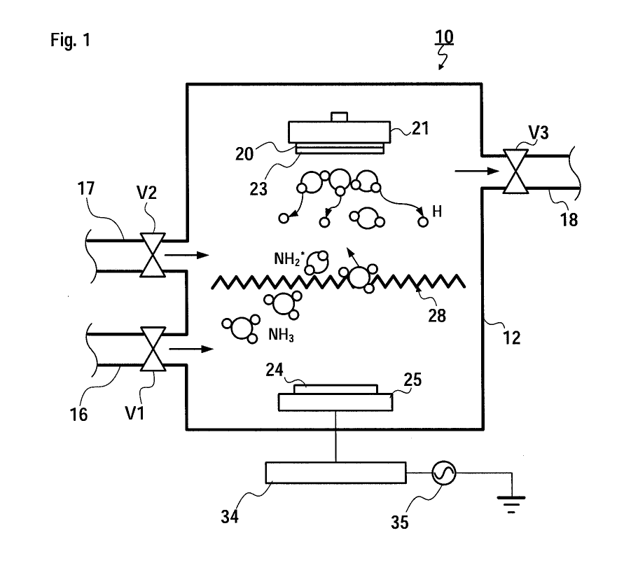

The production method of the present invention may be practiced using the production apparatus shown in FIG. 1, for example. Production apparatus 10 for a metal nitride film or the like includes reaction chamber 12 in which reduced pressure can be retained; inert gas supply duct 16 for supplying inert gas into reaction chamber 12; source gas supply duct 17 for supplying a source gas containing atoms selected from the group consisting of nitrogen atoms, oxygen atoms and carbon atoms into reaction chamber 12; and exhaust duct 18 for exhausting inert gas or used source gas from reaction chamber 12. Note that there is no need to provide separate ducts as inert gas supply duct 16 and source gas supply duct 17; one duct may be used that serves as both of inert gas supply duct 16 and source gas supply duct 17.

In reaction chamber 12 there are provided substrate holder 21 for supporting substrate 20; sputtering cathode 25 that is necessary for depositing metal film 23 onto substrate 20 by sputtering; and metal catalyst 28 that is necessary for radicalizing a source gas. Reaction chamber 12 is vacuumed under normal operation conditions, and is maintained in vacuum during sputtering and radical treatment. The positions of substrate holder 20 and sputtering cathode 25 may be reversed. Alternatively, they may be arranged side by side (as opposed to vertically) as long as they face each other.

Sputtering cathode 25 is connected to high frequency power source 35 via matching box 34. Other than the high frequency power source, DC or microwave power source can be employed. Matching box 34 is a device for effectively using energy delivered from high frequency power source 35 as necessary. Sputtering cathode 25 has target 24 for forming metal film 23, which is attached on the substrate-side surface. Sputtering cathode 25 constitutes a plasma generating mechanism together with a sputtering anode (not shown) attached to substrate holder 21. The plasma generating mechanism refers to a mechanism by which electrons or ions that are necessary for the sputtering of target 24 are generated. Here, sputtering cathode 25 and sputtering anode serve as sputtering electrodes. In the present invention the region between the sputtering electrodes, through which electrons or ions flow, is referred to as a “plasma region.”

As metal catalyst 28, any high-melting point or noble metal, including tungsten, molybdenum etc. is employed, as noted above. Upon radical treatment of metal film 23 formed on the substrate, a current is allowed to flow in metal catalyst 28 so that it is kept heated. Metal catalyst 28 is positioned so as to avoid the plasma region. For example, as shown in the drawing, it is placed along the side wall of reaction chamber 12.

When a metal nitride film or the like is to be produced, reaction chamber 12 is first returned to atmospheric pressure from vacuumed pressure, followed by attachment of substrate 20 to a predetermined position of substrate holder 21. Here, substrate 20 may be attached at a position facing target 24 so that they are in parallel with each other. Valve V3 is then opened to exhaust air from reaction chamber 12 through exhaust duct 18 to vacuum reaction chamber 12. At this point, reaction chamber 12 may be exhausted to a desired level of vacuum via exhaust duct 18.

While maintaining reaction chamber 12 under vacuum, valve V1 is opened to feed inert gas in reaction chamber 12. The pressure of the inert gas is maintained at a desired level by adjusting valve V3, and power is given to sputtering cathode 25 by turning on high frequency power source 35. At this point, a plasma is generated between the sputtering anode attached to substrate holder 21 and the sputtering cathode as a counter electrode. Inert gas ions excited in the plasma region with which target 24 is bombarded, ejecting atoms of target 24 for deposition onto substrate 20. In this way metal film 23 is formed on substrate 20.

After forming metal film 23 having a desired thickness, the inert gas used for sputtering is exhausted by opening valve V3 so that reaction chamber 12 is exhausted to a desired level of vacuum. Thereafter, valve V2 is opened to supply a source gas into reaction chamber 12 via source gas supply duct 17. Metal catalyst 28 is heated by application of a current. The temperature of heated metal catalyst 28 is not specifically limited; it is only necessary that metal catalyst 28 be heated to a temperature sufficient to activate atoms contained in the source gas. The source gas contacts heated metal catalyst 28. This activates given atoms of the source gas to generate radicals, which are readily reacted with metal film 23 on substrate 20 to form a metal nitride film, a metal oxide film, a metal carbide film or a film of composite material thereof.

It is not necessary in the present invention to heat metal film 23 to be reacted with radicals to high temperatures. For example, even when the temperature of metal film 23 is set to 300° C. or to 100° C. or below, or even when it is not heated at all, suitable reactions occur between metal film 23 and radicals. In order to retain the temperature of metal film 23 at 300° C. or below, substrate 20 may not be heated at all or may be heated to a level that causes the temperature of metal film 23 to be 300° C. or below.

After the reaction between metal film 23 and predetermined radicals is terminated, valve V3 is opened to exhaust the gas inside reaction chamber 12 via exhaust duct 18. The time at which this reaction is terminated may be appropriately determined according to the desired thickness, etc., of the resultant metal nitride film or the like. When it is confirmed that the metal nitride film or the like has a desired thickness, substrate 20 on which the film is formed is taken out from reaction chamber 12. Substrate 20 can be readily taken out from reaction chamber 12 by, after exhausting the used source gas from reaction chamber, closing valve V3 and opening valve V1 to supply inert gas into reaction chamber 12 so that reaction chamber 12 is returned to atmospheric pressure. In place of inert gas, dried air or dried nitrogen gas may be fed in reaction chamber 12. In this case, a gas inlet and a valve for gases other than inert gas and source gas are provided.

The metal nitride film or the like produced with a production apparatus like that shown in FIG. 1 is obtained by nitridization, oxidization or carbonization of a metal film with less amounts of impurities, which is produced by sputtering, by treatment with radicals. That is, the metal film can be reacted with radicals at low temperatures and the resultant metal film may be of high quality. Note that, according to the intended thickness of the metal nitride film or the like, the process of formation of a metal film by sputtering and radicalization of the metal film may be repeated.

FIG. 1 shows a production apparatus in which formation of a metal film by sputtering and reaction between the metal film and radicals are carried out in the same chamber. The configuration of the production apparatus is not specifically limited; formation of metal film and radical treatment maybe carried out indifferent chambers. In this case, a chamber in which a sputtering cathode is provided, and a chamber in which a metal catalyst is provided may be prepared separately. This configuration makes it possible to control the metal film formation conditions and radical reaction conditions separately, and thus to produce a metal nitride film or the like with higher quality.

The production apparatus of the present invention may be an apparatus that produces a metal nitride film or the like by forming a metal film by evaporation and reacting the metal film with radicals. In this case, the production apparatus may include a substrate holder; a metal evaporation source containing a constituent element of a metal film to be formed; a heating mechanism for heating the vapor deposition source; a source gas supply section; and a metal catalyst for generating radicals by activating the source gas. The metal catalyst may serve as the evaporation source. However, it is preferably provided at a position where direct contact with vaporized components from the evaporation source can be avoided.

In particular, the metal nitride film produced in the present invention (hereinafter also referred to as “metal nitride film in the present invention”) may have low resistance depending on the kind of the constituent metal. “Low resistance” means that resistance is low to an extent that the metal film is applicable for an interconnect process. For example, the resistance is preferably about 300 μΩcm or less when the film thickness is about 15 nm. The term “applicable for an interconnect process” encompasses the fact that the metal film can be applicable as a diffusion barrier for a copper or aluminum interconnection. The metal nitride film in the present invention can have a resistance of 50-100 μΩcm, a resistance that is much smaller than those of metal nitride films produced by conventional CVD and that is comparable to those of metal nitride films produced by reactive sputtering.

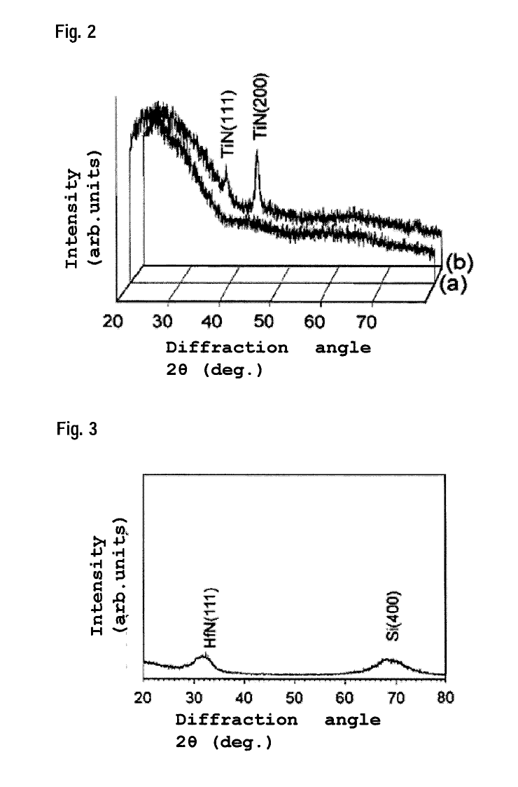

It is concluded from the following results that a metal nitride film in the present invention is composed of ultra-fine crystals or amorphous phase. FIG. 2 shows an X-ray diffraction pattern (a) of a titanium nitride film (thickness=about 20 nm) formed on a glass substrate according to the production method of the present invention, and an X-ray diffraction pattern (b) of a titanium nitride film (thickness=about 100 nm) formed on a glass substrate by reactive sputtering. As shown in FIG. 2, while distinct reflection lines derived from the TiN (111) plane and TiN (200) plane were observed in the pattern (b), in the pattern (a), no distinct reflection lines were observed, but a broad pattern was observed near the 2θ value corresponding to the reflection line derived from the TiN (200) plane.

FIG. 3 shows an X-ray diffraction pattern of a hafnium nitride film (thickness=9 nm) formed on a SiO₂/Si substrate according to the production method of the present invention. As shown in FIG. 3, a very small broad reflection line was observed near the 2θ value corresponding to the HfN (111) plane.

These results suggest that the metal nitride film in the present invention is composed of ultra-fine crystals (nanocrystalline phase) or amorphous phase.

The metal nitride film or the like of the present invention, even when composed of an amorphous phase or nanocrystalline phase, may not undergo structural change by heat treatment. “Heat treatment” means heating at 500° C. in a vacuum, for example. Whether the metal nitride film or the like has an amorphous phase or nanocrystalline phase is determined by transmission electron microscopy or electron beam diffraction, or even by thin film mode X-ray diffraction. “Nanocrystalline phase” refers to a phase composed of crystalline grains with particle diameters of several nanometers (e.g., 1-10 nm).

The metal nitride film in the present invention may have an amorphous structure and low resistance. “Low resistance” means, for example, a resistance of 300 μΩcm or less, preferably 300 μΩcm or less when the film thickness is 15 nm.

The metal nitride films or the like in the present invention may be stacked on top of one another while interposing metal films between them to form a laminate with a sandwich structure.

The metal nitride film or the like produced in the present invention is used in any intended application, for example, as a coating film. This is because the metal nitride films or the like in the present invention may have a flat surface, which is suitable as a coating film.

Moreover, the metal nitride film or the like in the present invention is used as a barrier for a semiconductor device. Among other metal nitride films, a titanium nitride film, zirconium nitride film, hafnium nitride film, vanadium nitride film, niobium nitride film, etc., inherently have low resistance and therefore are more suitable as a barrier for a semiconductor device.

[Manufacturing Method for Semiconductor Device]

The production method of the present invention for producing a metal nitride film or the like can also be suitably used as a method for producing a barrier for a semiconductor device. More specifically, a manufacturing method of the present invention for manufacturing a semiconductor device is a method of manufacturing a semiconductor device that includes a substrate, an interlayer dielectric film formed on the substrate, a barrier formed on the interlayer dielectric film, and a metal interconnection formed on the barrier, the method including the steps of (a) preparing a substrate having an interlayer dielectric film on which a metal film is formed by physical vapor deposition; and (b) allowing radicals, which have been generated by bringing a source gas containing nitrogen atoms, oxygen atoms or carbon atoms into contact with a metal catalyst, to react with the metal film to form as a barrier a metal nitride film, metal oxide film, metal carbide film or film of composite material thereof. Other than the barrier formation method consisting of the steps (a) and (b), any known semiconductor device manufacturing step can be employed.

The barrier according to the present invention for a semiconductor device is produced by reacting a metal film, which has been formed by physical vapor deposition, with radicals generated from a source gas. Examples of the physical vapor deposition include the above-described sputtering method and vapor evaporation method. The sputtering method has been explained in detail above and therefore will not be described here. The sputtering method has the advantage of producing metal films with low resistance, and the evaporation method has the advantages of producing a relatively thick layer in a short time, for example.

The metal film to be reacted with radicals may be retained at 300° C. or below, or 100° C. or below. The barriers produced in this way have low resistance as with metal nitride films obtained by reactive sputtering. Moreover, they can be formed on semiconductor devices that include a substrate made of material to which heat cannot be applied, e.g., plastic substrates. By appropriately adjusting the metal film thickness and/or reaction time between the metal film and radicals, the barrier thickness can be reduced to as small as 5 nm or less. The reason why the deposition temperature of a metal nitride film or the like upon formation of a semiconductor device barrier can be reduced is the same as in the above description of the production method of a metal nitride film or the like.

The barrier in a semiconductor device may be formed directly on the substrate; on the capping layer;

between metal interconnections; between the interlayer dielectric film and metal interconnection formed on the substrate; on the semiconductor film; and so forth. Any other configuration can be employed.

The material of the interlayer dielectric film according to the present invention contained in a semiconductor device maybe silicon oxide; however, more thermally unstable (i.e., low heat resistant) materials may be employed. In the manufacturing method of the present invention for manufacturing a semiconductor device, since barrier formation does not require high temperature, thermally unstable materials can be actively used for the formation of the interlayer dielectric film.

More specifically, it is possible to use SiOC, SiOC, porous films, polymer films, etc., which are known as low-permittivity materials, for the interlayer dielectric film.

The metal interconnection contained in the semiconductor device according to the present invention is not specifically limited, and a copper or aluminum interconnection can be employed. Since the barrier for a semiconductor device in the present invention can have low resistance, signal delay due to increased electric capacitance between interconnections, which is a problem considered pertinent in copper or aluminum interconnections, may be alleviated.

### Example 1

A titanium film with a thickness of about 1 nm was deposited onto a thermal SiO₂/Si substrate (not heated) by sputtering using argon gas (target power=50 W). Using a tungsten filament as a metal catalyst, ammonia gas was radicalized, and the titanium film was reacted with the generated radicals for radical nitridization reaction for 5 minutes without heating the substrate. This process was repeated 5 times to form a titanium nitride film with a thickness of about 5 nm. At room temperature, a 100 nm-thick copper film was then formed on the titanium nitride film by reactive sputtering (target voltage=500V, current=70 mA) using argon gas to obtain a Cu/TiNₓ/SiO₂/Si structure.

### Comparative Example 1

A 5 nm-thick titanium nitride film was deposited onto a thermal SiO₂/Si substrate (heated to 350° C.), which is similar to that in Example 1, by reactive sputtering (target voltage=1 kV, current=80 mA) using a mixture gas of argon gas and nitrogen gas (10 volume %). At room temperature, a 100 nm-thick copper film was then formed on the titanium nitride film by sputtering (target voltage=500V, current=70 mA) using argon gas to obtain a Cu/TiNₓ/SiO₂/Si structure.

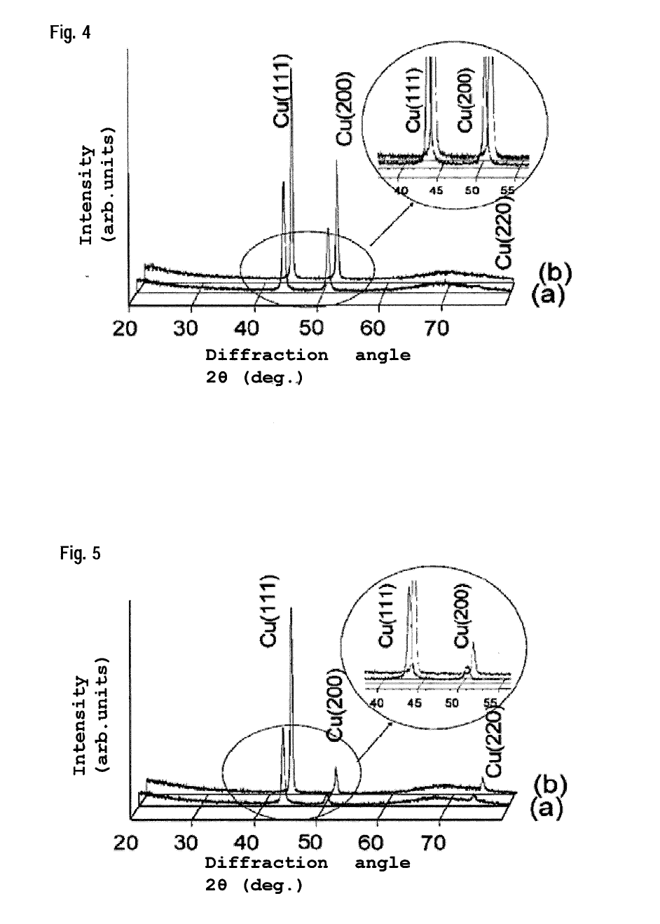

The Cu/TiNₓ/SiO₂/Si structures obtained in Example 1 and Comparative Example 1 were evaluated for their X-ray diffraction pattern by the 8-28 method. The measured X-ray diffraction patterns correspond to patterns (a) in FIGS. 4 and 5, respectively. In addition, the X-ray diffraction patterns of the Cu/TiNₓ/SiO₂/Si structures were measured by the θ-2θ method after heat treatment at 500° C. for 30 minutes in a vacuum of 10⁻⁷ Torr. The X-ray diffraction patterns measured after heat treatment correspond to patterns (b) in FIGS. 4 and 5, respectively.

FIG. 4 shows that in the X-ray diffraction patterns of the structure of Example 1, both before and after heat treatment, only reflection lines derived from copper were observed and no reflection lines were observed that are derived from reaction products generated by heat treatment. This demonstrates that the metal nitride film obtained by the product ion method of the present invention, even when it has a thickness of 5 nm, can prevent copper diffusion or copper reaction at 500° C.

Meanwhile, as shown in the X-ray diffraction patterns (a) and (b) of FIG. 5 which are X-ray diffraction patterns of the structure of the Comparative Example 1, both before and after heat treatment, only reflection lines derived from copper were observed and no reflection lines were observed that are derived from reaction products generated by heat treatment.

The results shown in FIGS. 4 and 5 demonstrate that the titanium nitride film obtained by the production method of the present invention has barrier characteristics comparable to those of titanium nitride films obtained by reactive sputtering.

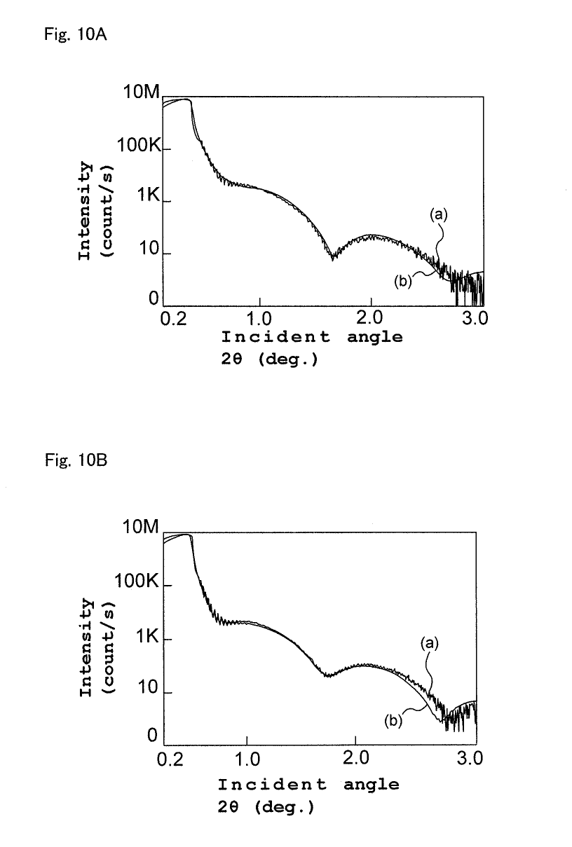

Next, grazing incidence X-ray reflectivity (GIXR) was carried out for the structure of Example 1 both before and after heat treatment. The results are shown in FIG. 10A (before heat treatment) and in FIG. 10B (after heat treatment). In either case, the results are closely consistent with those of a simulation using a Cu surface-oxidized film/Cu/TiNₓ/SiO₂/Si model. GIXR is known to be capable of detection of even an interlayer of about 1.3 nm thickness. Thus, these results suggest that there are no interlayers formed in the structure of Example 1, both before and after heat treatment.

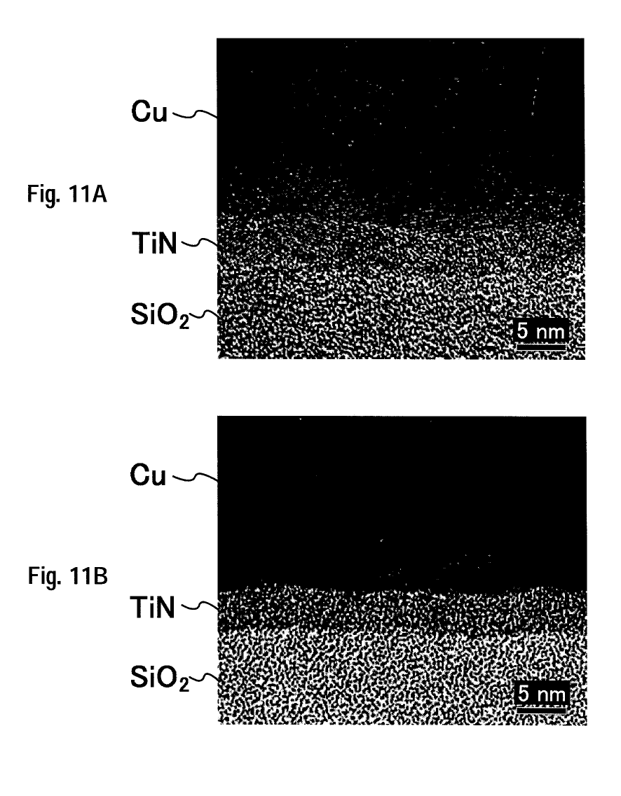

Cross-sectional TEM images of the structure of Example 1 before and after heat treatment are shown in FIG. 11A (before heat treatment) and in FIG. 11B (after heat treatment). FIGS. 11A and 11B show that, both before and after heat treatment, a TiNₓ barrier is formed as a continuous, uniform film without involving formation of any interlayer.

Table 1 shows comparisons between the barrier characteristics of the TiNₓ barrier obtained in accordance with Example 1 and those of TiNₓ barriers obtained using conventional deposition methods.

TABLE 1

| | | Substrate | Film |
|---|---|---|---|
| Deposition | Resistance | temperature | thickness |
| method | (μΩcm) | (° C.) | (nm) |
| Reactive sputtering | 41~98 | 350~400 | 40~100 |
| CVD | 300~2000 | 350~400 | 50~100 |
| ALD | 350~104 | 250~390 | 20~33 |
| Example 1 | 50 | Not heated | 20 |

Characteristics of TiNₓ barriers produced by different deposition methods

Data regarding reactive sputtering shown in Table 1 are described in the following literatures:

G. S. Chen, J. J. Guo, C. K. Lin, C.-S. Hsu, L. C. Yang, and J. S. Fang, J. Vac. Sci. Technol., A20, 479 (2002);

S.-K. Rha, S.-Y. Lee, W.-J. Lee, Y.-S. Hwang, C.-O. Park,

D.-W. Kim, Y.-S. Lee, and C.-N. Whang, J. Vac. Sci. Technol., B16, 2019 (1998); and

K.-C. Park, K.-B. Kim, I. J. M. M. Raaijmakers, and K. Ngan, J. Appl. Phys. 80, 5674 (1996).

Data regarding CVD shown in Table 1 are described in the following literatures:

K.-C. Park, K.-B. Kim, I. J. M. M. Raaijmakers, and K. Ngan, J. Appl. Phys. 80, 5674 (1996);

D.-H. Kim, S.-L. Cho, K.-B. Kim, J. J. kim, J. W. Park, and J. J. Kim, Appl. Phys. Lett. 69, 4182 (1996);

S.-C. Chang and Y.-L. Wang, Electrochemical and Solid-State Lett., 9, G130 (2006); and

K.-C. Park, S.-H. Kim, and K.-B. Kim, J. Electrochem. Soc., 147, 2711 (2000).

Data regarding ALD shown in Table 1 are described in the following literatures:

M. Harada, K. Kamada, S. Toyoda, N. Katou, H. Ushikwa, Advanced Metallization Conference 2006, Asian Session, 7-3, 114 (2006);

J. W. Elam, M. Schuisky, J. D. Ferguson, S. M. George, Thin Solid Films, 436, 145 (2003); and

S. Li, C. Q. Sun, H. S. Park, Thin Solid Films, 504, 108 (2006).

As shown in Table 1, the TiNₓ barrier obtained in Example 1 has a resistance comparable to that of a TiNₓ barrier obtained by reactive sputtering. In addition, although not shown in Table 1, the TiNₓ barrier of Example 1 has a density close to that of the TiNₓ barrier obtained by reactive sputtering.

These results suggest that the TiNₓ barrier of Example 1 has lesser impurities than TiNₓ barriers obtained by ALD or CVD, and contains Ti atoms and nitrogen atoms bonded together in good condition. Thus, with the present invention, it is possible to produce, without heating the substrate, a barrier comparable to that obtained by conventional reactive sputtering.

### Example 2

A hafnium film with a thickness of about 3 nm was deposited onto a thermal SiO₂/Si substrate (not heated) by sputtering (target power=30 W) using argon gas. Using a tungsten filament as a metal catalyst, ammonia gas was radicalized, and the hafnium film was reacted with the generated radicals for radical nitridization reaction for 5 minutes without heating the substrate. Thisprocess was repeated 5 times to form a hafnium nitride film with a thickness of about 15 nm. At room temperature, a 100 nm-thick copper film was then formed on the hafnium nitride film by sputtering (target voltage=500V, current=70 mA) using argon gas to obtain a Cu/HfNₓ/SiO₂/Si structure.

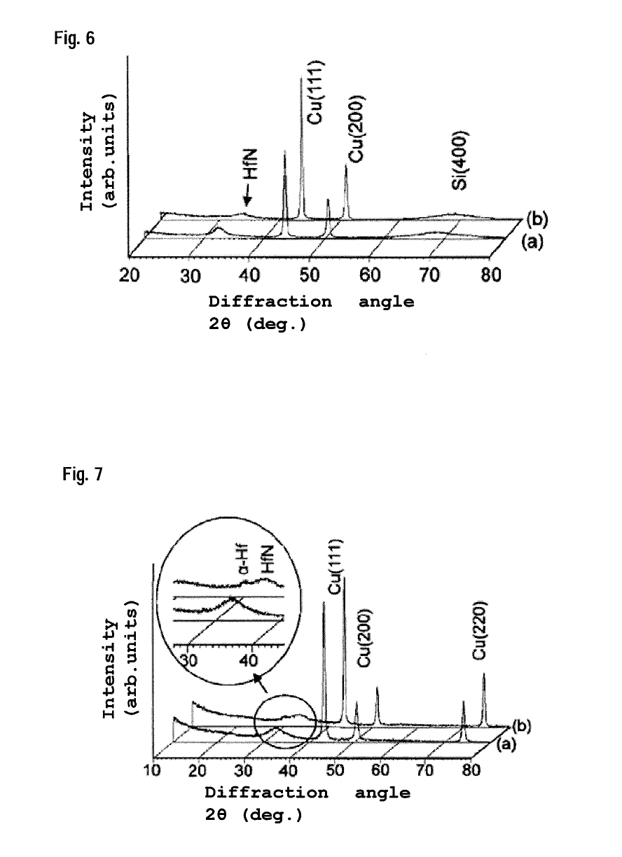

The Cu/HfNₓ/SiO₂/Si structure obtained in Example 2 was then evaluated for X-ray diffraction patterns by the θ-2θ method and thin-film method. The results are shown as the patterns (a) in FIGS. 6 and 7. In addition, the X-ray diffraction patterns of the Cu/HfNₓ/SiO₂/Si structure were measured by the θ-2θ method and thin-film method after heat treatment at 500° C. for 30 minutes in a vacuum of 10⁻⁷ Torr. The results are shown as the patterns (b) in FIGS. 6 and 7.

As shown in FIG. 6, in the X-ray diffraction patterns (as measured by the θ-2θ method), both before and after heat treatment, a very small broad reflection line derived from hafnium nitride was observed near 31.92° and a large sharp reflection line derived from the Cu (111) plane was observed, but no reflection lines derived from reaction products generated by heat treatment, such as copper silicide and copper-hafnium alloys, were observed. These results suggest that the hafnium nitride film obtained by the production method of the present invention prevented copper-derived reactions during heat treatment at 500° C., and has barrier characteristics.

As shown in FIG. 7, the very small broad reflection line derived from hafnium nitride observed near 31.92° in the X-ray diffraction pattern (as measured by the θ-2θ method) before heat treatment is divided into two peaks positioned near 30.28° and 32.64° after heat treatment. These results suggest that the thermally-treated hafnium nitride film contains both nitrogen-containing a-hafnium and hafnium nitride, revealing that the present invention can control the nitrogen concentration in the hafnium nitride film.

### Example 3

A hafnium film with a thickness of about 2 nm was deposited onto a thermal SiO₂/Si substrate (not heated) by sputtering (target power=30 W) using argon gas. Using a tungsten filament as a metal catalyst, ammonia gas was radicalized, and the hafnium film was reacted with the generated radicals for radical nitridization reaction for 5 minutes without heating the substrate. This process was repeated 5 times to form a hafnium nitride film with a thickness of about 10 nm. At room temperature, a 100 nm-thick copper film was then formed on the hafnium nitride film by sputtering (target voltage=500V, current=70 mA) using argon gas to obtain a Cu/HfNₓ/SiO₂/Si structure.

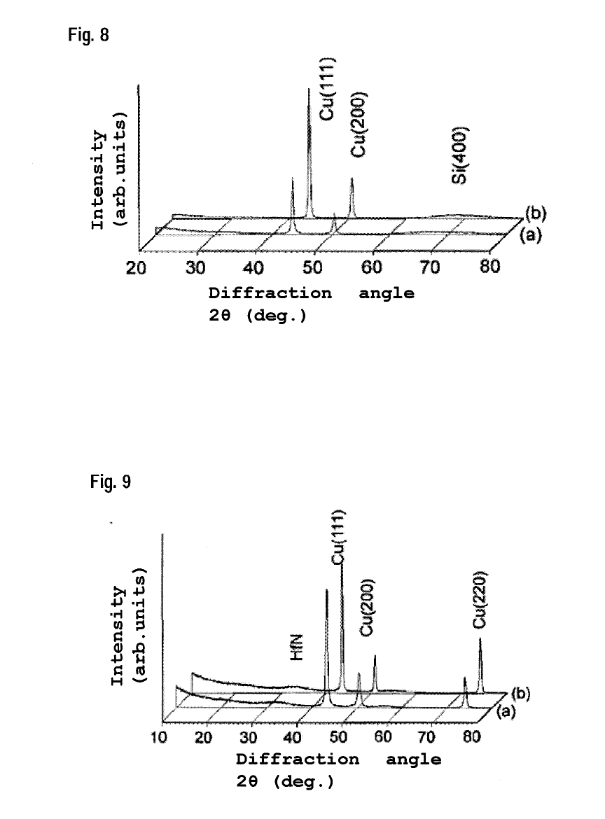

The Cu/HfNₓ/SiO₂/Si structure obtained in Example 3 was then evaluated for X-ray diffraction patterns by the θ-2θ method and thin-film method. The results are shown as the patterns (a) in FIGS. 8 and 9. In addition, the X-ray diffraction patterns of the Cu/HfNₓ/SiO₂/Si structure were measured by the θ-2θ method and thin-film method after heat treatment at 500° C. for 30 minutes in a vacuum of 10⁻⁷ Torr. The results are shown as the patterns (b) in FIGS. 8 and 9.

As shown in FIG. 8, in the X-ray diffraction patterns (as measured by the θ-2θ method), both before and after heat treatment, a very small broad reflection line derived from hafnium nit ride was observed near 31.92° and a large sharp reflection line derived from the Cu (111) plane was observed, but no reflection lines derived from reaction products generated by heat treatment, such as copper silicide and copper-hafnium alloys, were observed. These results suggest that the hafnium nitride film obtained by the production method of the present invention prevents copper-derived reactions during heat treatment at 500° C., and has barrier characteristics. Also, These results are consistent with the results of FIG. 6.

As shown in FIG. 9, even by observation by the thin-film method, no changes were observed in the X-ray diffraction pattern (as measured by the θ-2θ method) between before and after heat treatment; even the very small broad reflection line near the 31.92° did not change. In Example 2 where the hafnium nitride film thickness is about 15 nm, heat treatment divided the reflection line near 31.92° into two peaks as shown in FIG. 7, suggesting that the hafnium nitride film contains both nitrogen-containing α-hafnium and hafnium nitride. Meanwhile, in Example 3 where the hafnium nitride film thickness is about 10 nm, it was suggested that a film made of hafnium nitride was formed in which the ratio of nitrogen atoms to hafnium atoms is 1:1, revealing that the nitrogen concentration can be controlled by adjusting the film thickness.

The present application claims the priority of Japanese Patent Application No. 2006-172584 filed on Jun. 22, 2008, the entire contents of which are herein incorporated by reference.

### INDUSTRIAL APPLICABILITY

A metal nitride film or the like produced in accordance with the present invention is a metal film of high purity that contains lesser impurities than metal films produced by conventional methods such as CVD and can be produced at lower temperatures than metal films produced by conventional reactive sputtering; therefore, it can be used in a variety of applications. Moreover, the production method of the present invention has the advantage of low costs since the method can be practiced by placing a filament- or wire-shaped metal catalyst in a conventional sputtering apparatus.

In particular, a metal nitride film produced in accordance with the present invention can have low resistance and ultra-thin thickness of the order of several nanometers and thus can be suitably used as a barrier film for semiconductor devices. In order to make a barrier film with a thickness of the order of several nanometers, it may be that the following problems should be resolved: (1) How suppression of formation of an intermixing layer can be achieved at the interface between an interconnection and interlayer dielectric film; and (2) how control of grain size capable of forming a continuous layer can be achieved. In response to these problems, the present invention (1) can produce smaller grain sizes than conventional reactive sputtering, or can make a metal nitride film or the like with an amorphous structure, and also (2) can suppress formation of an intermixing layer by abundantly providing nitrogen atoms only in the vicinity of the interface. The present invention, of course, suppresses formation of an intermixing layer by heating the substrate. Accordingly, the present invention can also contribute to provide a ultra-thin barrier film.

What is claimed is:

1. A production apparatus for producing on a substrate a film selected from the group consisting of ametal nitride film, a metal oxide film, a metal carbide film and a film of composite material thereof, comprising:
a substrate holder for supporting the substrate;
a chamber capable retaining a reduced pressure therein;
an inert gas supply section that supplies inert gas into the chamber;
a source gas supply section that supplies a source gas containing atoms selected from the group consisting of nitrogen atoms, oxygen atoms and carbon atoms into the chamber;
a target containing a constituent element of a metal film to be formed on the substrate;
a pair of sputtering electrodes for sputtering the target using the inert gas supplied from the gas supply section as a sputtering gas; and
a metal catalyst which generates radicals by activating the source gas and which is placed outside a plasma region formed by the pair of sputtering electrodes.

2. The production apparatus according to claim 1, wherein the pair of sputtering electrodes and metal catalyst are placed in the same chamber.

3. The production apparatus according to claim 1, wherein the pair of sputtering electrodes is placed in a different chamber than the metal catalyst. 5

4. The production apparatus according to claim 1, wherein the production apparatus is for practicing a production method comprising:
a first step of forming a metal film on the substrate by physical vapor deposition, the metal film having a thickness of 1 to 10 nm; and
a second step of allowing radicals, which have been generated by bringing a source gas containing atoms selected from the group consisting of nitrogen atoms, oxygen atoms and carbon atoms into contact with a metal catalyst, to react with the metal film.

5. A production apparatus for producing on a substrate a film selected from the group consisting of a metal nitride film, a metal oxide film, a metal carbide film and a film of composite material thereof, comprising:
a substrate holder for supporting the substrate;
a chamber capable retaining a reduced pressure therein;
a source gas supply section that supplies a source gas containing atoms selected from the group consisting of nitrogen atoms, oxygen atoms and carbon atoms into the chamber;
a metal evaporation source containing a constituent element of a metal film to be formed;
a heating mechanism for heating the metal evaporation source; and
a metal catalyst which generates radicals by activating the source gas and which serves as, or is placed near the heating mechanism.

6. The production apparatus according to claim 5, wherein the production apparatus is for practicing a production method comprising:
a first step of forming a metal film on the substrate by physical vapor deposition, the metal film having a thickness of 1 to 10 nm; and
a second step of allowing radicals, which have been generated by bringing a source gas containing atoms selected from the group consisting of nitrogen atoms, oxygen atoms and carbon atoms into contact with a metal catalyst, to react with the metal film.
